(19) United States
(12) Patent Application Publication
(10) Pub. No.: US 2024/0409397 A1
(43) Pub. Date: Dec. 12, 2024

(54) MEMS SWITCH UTILIZING CONDUCTIVE BARRIER LAYER

(71) Applicant: Menlo Microsystems, Inc., Irvine, CA (US)

(72) Inventors: Christopher F. Keimel, Niskayuna, NY (US); Chris Nassar, Hudson, NY (US); Aric Shorey, Pittsford, NY (US); Matthew Strohmayer, Glennville, NY (US)

(21) Appl. No.: 18/330,565

(22) Filed: Jun. 7, 2023

(51) Int. Cl. B81B 7/00; B81C 1/00

(52) U.S. Cl. CPC B81B 7/007; B81C 1/00793; B81B 2201/018; B81B 2207/095; B81C 2201/0197

(57) ABSTRACT

A method of preventing corrosion associated with an electrically-conductive through-glass via (TGV) may comprise forming a TGV in a glass substrate for use in a microelectromechanical system (MEMS) device. The TGV has a first end and a second end, and at least partially comprises copper. The method may further comprise applying a conductive barrier layer on the first end of the TGV and/or the second end of the TGV, and applying a metal layer over the conductive barrier layer. The method may further comprise extending the conductive barrier layer over the first end of the TGV, and over at least a portion of the glass substrate encompassing the end of the TGV, such that the conductive barrier layer overlaps a boundary between the TGV and the glass substrate.

### BACKGROUND

A copper-based electrical via may be used to communicate an electrical signal into a microelectromechanical system (MEMS) component. The copper-based via may be covered by a conductive metal pad to provide an effective electrical interface to the encapsulated MEMS device and/or an external device or system. Under certain conditions, the conductive metal pad may exhibit corrosion, which detrimentally affects the performance of the MEMS component.

### SUMMARY

The embodiments described herein are directed to an electrically conductive barrier layer applied between the copper through-glass via (TGV) and any associated gold layers, to reduce or eliminate migration of copper through the gold layers, and consequently reduce or eliminate formation of contaminants (e.g., CuO) on surfaces of the gold layers.

In one aspect, the invention may be a method of preventing corrosion associated with an electrically-conductive through-glass via (TGV). The method may comprise forming a TGV in a glass substrate for use in a microelectromechanical system (MEMS) device. The TGV may have a first end and a second end, and at least partially comprise copper. The method may further comprise applying a conductive barrier layer on the first end of the TGV and/or the second end of the TGV.

The method may further comprise applying a metal layer over the conductive barrier layer. The method may also comprise extending the conductive barrier layer over the first end of the TGV, and over at least a portion of the glass substrate encompassing the end of the TGV, such that the conductive barrier layer overlaps a boundary between the TGV and the glass substrate. The method may further comprise applying the conductive barrier layer using an electroless plating process. The electroless plating technique may be electroless palladium and immersion gold (EPIG). The electroless plating technique may be immersion gold, electroless palladium, and immersion gold (IGEPIG). The electroless plating technique may be Electroless Nickel and Immersion Gold (ENIG).

In an embodiment, forming the TGV in the glass substrate may further comprise forming a planar TGV in the glass substrate. Forming the TGV in the glass substrate may further comprise forming a pinched TGV in the glass substrate.

In another aspect, the invention may be an electrically-conductive through-glass via (TGV) structure that comprises a TGV formed in a glass substrate for use in a microelectromechanical system (MEMS) device. The TGV may have a first end and a second end, and at least partially comprise copper. The structure may further comprise a conductive barrier layer applied on the first end of the TGV and/or the second end of the TGV.

The structure may further comprise a metal layer disposed over the conductive barrier layer. The conductive barrier layer may extend over the first end of the TGV, and over at least a portion of the glass substrate encompassing the end of the TGV, such that the conductive barrier layer overlaps a boundary between the TGV and the glass substrate. The conductive barrier layer may be applied using an electroless plating process. The electroless plating technique may be electroless palladium and immersion gold (EPIG). The electroless plating technique may be immersion gold, electroless palladium, and immersion gold (IGEPIG). The electroless plating technique may be Electroless Nickel and Immersion Gold (ENIG). The TGV may be a planar TGV. The TGV may be a pinched TGV.

In another aspect, the invention may be a microelectromechanical system (MEMS) component that comprises a glass substrate that hosts a MEMS device, a glass lid disposed on the glass substrate and encompassing the MEMS device within a cavity, a through-glass via (TGV) formed in the glass lid. The TGV may have a first end at an exterior of the glass lid, a second end that is electrically coupled to the MEMS device. The TGV may at least partially comprise copper. The MEMS component may further comprise a conductive barrier layer applied on the first end of the TGV and/or the second end of the TGV.

The conductive barrier layer may extend over the first end of the TGV, and over at least a portion of the exterior of the glass lid, such that the conductive barrier layer overlaps a boundary between the TGV and the glass lid.

### BRIEF DESCRIPTION OF THE DRAWINGS

The patent or application file contains at least one drawing executed in color. Copies of this patent or patent application publication with color drawings will be provided by the Office upon request and payment of the necessary fee.

The foregoing will be apparent from the following more particular description of example embodiments, as illustrated in the accompanying drawings in which like reference characters refer to the same parts throughout the different views. The drawings are not necessarily to scale, emphasis instead being placed upon illustrating embodiments.

FIGS. 1A and 1B illustrate components of a MEMS component.

FIG. 2 shows an example of barrier layer placement according to embodiments of the invention.

FIGS. 3A and 3B show cross-sectional and top views of a pinched via.

FIGS. 4A, 4B, and 4C show cross-sectional and top views of planar vias.

FIGS. 5A and 5B illustrate details of a barrier layer at the top of a via.

FIG. 6 shows barrier layer thickness and coverage characteristics at selected depths of a pinched via.

FIGS. 7A and 7B show via corrosion characteristics with and without a barrier layer in place.

### DETAILED DESCRIPTION

A description of example embodiments follows.

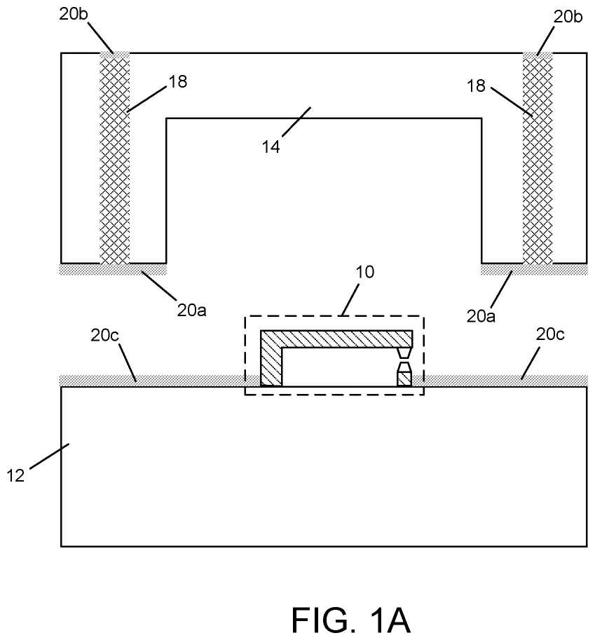

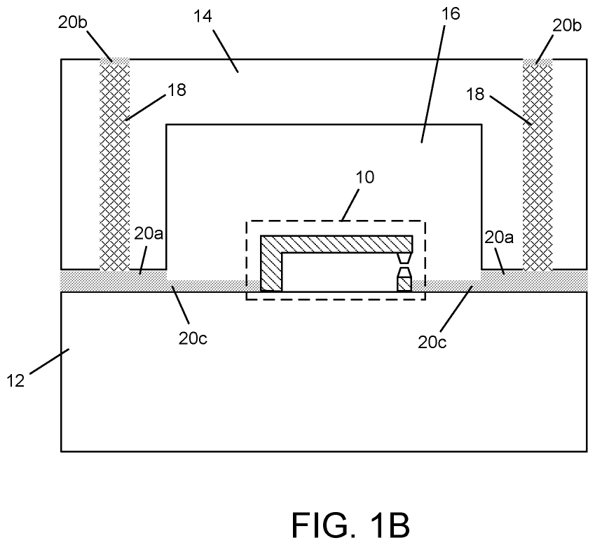

A microelectromechanical system (MEMS) component may consist of a two-part structure, as shown in FIG. 1A. The first part comprises a MEMS device structure 10 constructed on a glass substrate 12, and the second part comprises a glass lid or cap 14 that surrounds and covers the MEMS device structure 10, as shown in FIG. 1B, to form a hermetically sealed cavity 16 in which the MEMS device structure 10 resides. One or more electrical conductors may pass through the glass lid 14 to the MEMS device structure 10, to provide electrical access to the MEMS device structure 10 from outside the sealed cavity 16. These electrical conductors are in the form of through-glass vias (TGVs) 18 that facilitate the transmission of electrical signals through the glass lid 14 while maintaining the hermeticity of the sealed cavity 16.

The electrically conductive material within the TGV 18 may be copper, with a gold layer 20a coupled to the bottom (i.e., substrate-facing) end of the TGV 18, and a gold layer 20b (external bonding pad) coupled to the top end of the TGV 18. Gold layers 20c are disposed on the substrate 12 and electrically coupled to the MEMS device structure 10. The gold layer 20a at the bottom of the TGV 18 couples to the gold layer 20c on the substrate 12 by thermal-compression bonding, thereby forming the hermetically sealed cavity 16, as shown in FIG. 1B.

It is known that copper can readily diffuse through gold, especially at elevated temperatures. If copper from the TGV 18 diffuses through the gold layer 20a and into the oxygen containing cavity of the MEMS device 10, there is substantial risk of forming contaminants (e.g., cupric oxide—CuO) on the cavity-facing surface of the gold layer 20a. These contaminants can be detrimental to the performance of the MEMS device 10. Further, copper can migrate through the exterior gold layers 20b to form copper-contaminants on the external bonding pads, thereby increasing the likelihood of forming poor external electrical connections to the MEMS component.

The embodiments described herein are directed to an electrically conductive barrier layer or layers applied between (i) a copper (Cu) through-glass via (TGV) and (ii) each of one or more gold (Au) layers associated with the TGV. The barrier layer is configured to reduce or eliminate migration of Cu from the TGV through one or more associated Au layers.

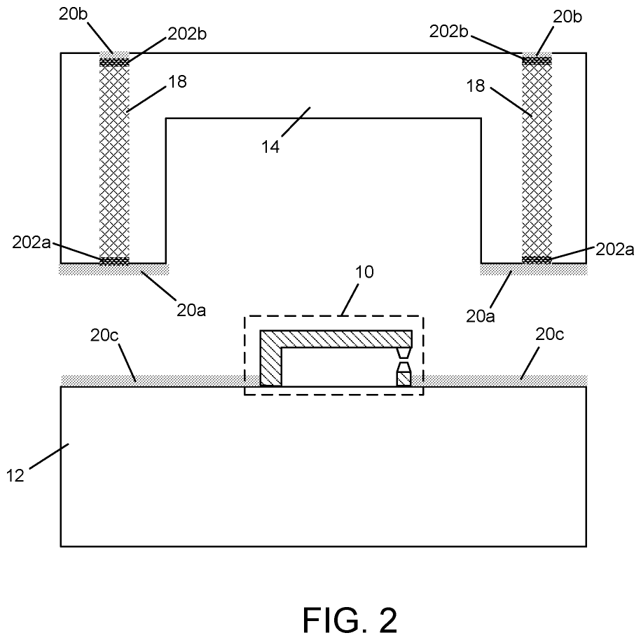

FIG. 2 illustrates an example of barrier layer placement according to the described embodiments. The examples in FIG. 2 are not necessarily drawn to scale, but are used to present conceptual descriptions. Similar to the structure shown in FIG. 1A, the cap 14 comprises a copper-based TGV 18 deployed within a glass lid 14, with a gold layer 20b coupled to the top end of the TGV 18 and a gold layer 20a coupled to the bottom end of the TGV 18. Although the TGV 18 in this example embodiment is described as being copper-based, it should be understood that in some embodiments the TGV may comprise copper, or a material that is mostly copper (e.g., greater than 95 percent copper) or a material that comprises some smaller portion that is copper (e.g., more than half copper), or a material that comprises less than half copper.

Barrier layer 202a is disposed between the TGV 18 and Au layer 20a at the bottom (i.e., substrate-facing) end of the TGV 18. Barrier layer 202b is disposed between the TGV 18 and the Au layer 20b at the top end of the TGV 18.

In the example embodiment described herein, the barrier layer comprises palladium (Pd). In alternative embodiments, the barrier layer may comprise a material such as nickel (Ni) or composites that include Pd and/or Ni, or other materials suitable for blocking Cu migration. The barrier layer should be of a sufficient thickness to prevent Cu migration into an adjacent metal layer (e.g., gold) at elevated temperatures (e.g., 300° C. to 400° C. for one to two hours). A sufficient thickness of the barrier layer may depend on device characteristics and physical parameters, and may be determined empirically, but a sufficient thickness is generally at least 250 nm for Pd, and at least 175 nm for Ni.

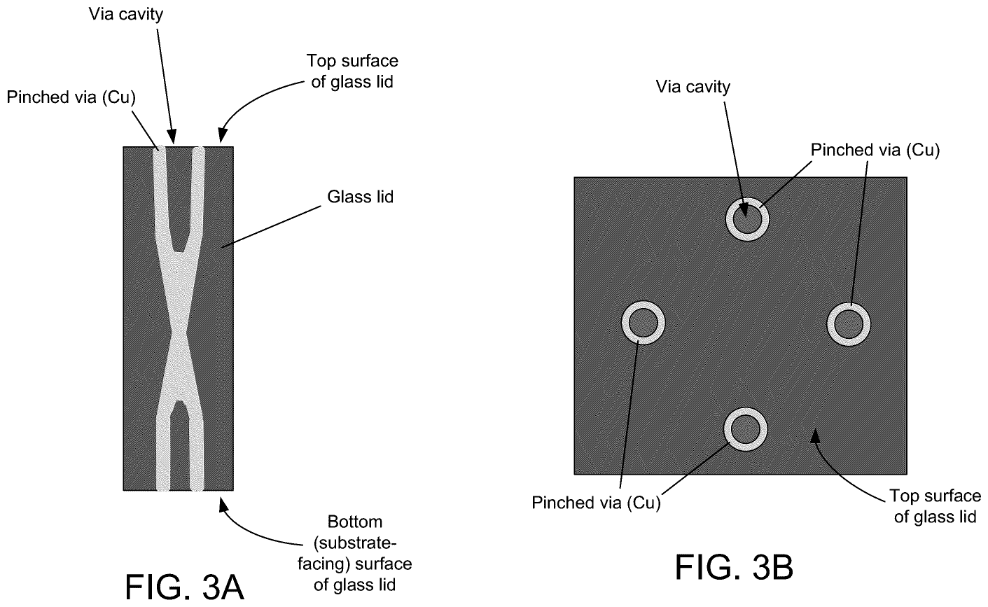

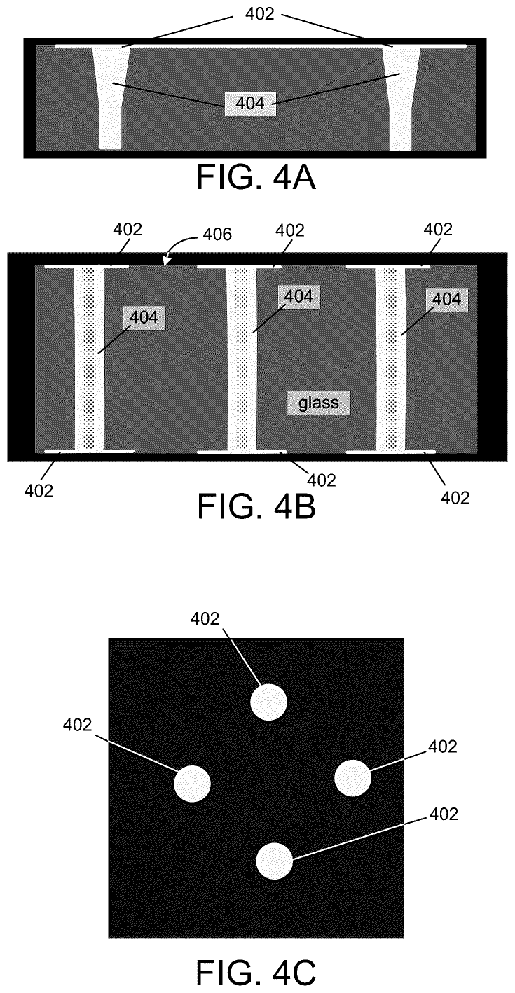

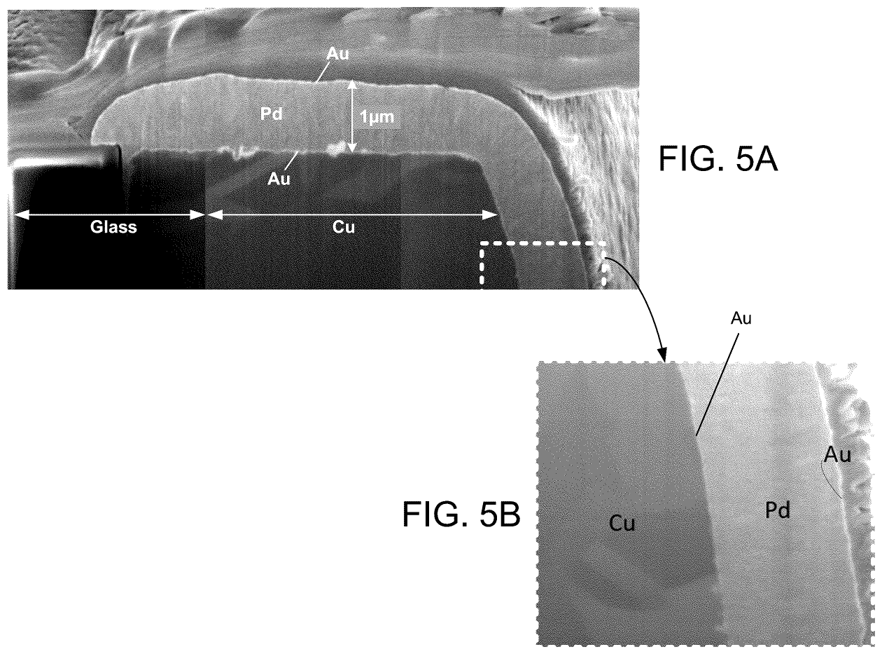

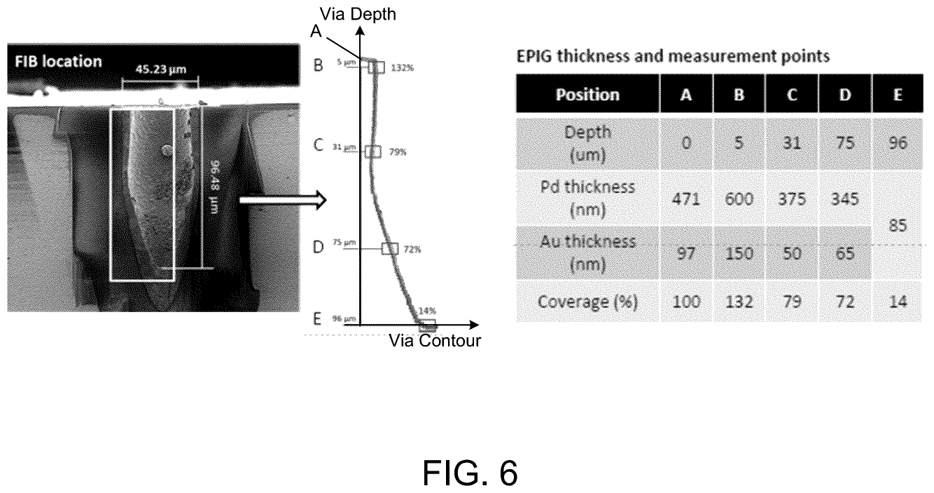

The process of deploying the barrier layer described herein may be integrated into the procedure for fabricating a microelectromechanical system (MEMS) component. In an example embodiment, the TGV may be fabricated and filled with copper during the MEMS component fabrication. The TGV could take on several forms including pinch vias (as shown in a cross-sectional view in FIG. 3A, a top view in FIG. 3B, and in FIGS. 5A, 5B, and 6), or several versions of planar vias (shown in FIGS. 4A, 4B, and 4C), where “planar” refers to the fact that the metallized top 402 of the via 404 is substantially co-planar with the glass surface 406 (to within manufacturing specifications). Other variations on these designs are also possible.

After the Cu-based vias are formed in the glass wafers, the glass wafers go through a metal finishing step where the conductive barrier layer is deposited or plated on top of the Cu-based via. This may include a pre-treatment of the Cu surface followed by the use of a catalyst, a barrier layer, and a final Au layer. Some cases of EPIG may incorporate a thin Ni or Au layer, for example, between the Cu and Pd, and in other cases the Pd may be plated directly onto the Cu with some pre-treatment (e.g., etching of the Cu).

There are several processes available for applying a conductive barrier layer, for example (i) Electroless Nickel and Immersion Gold (ENIG), (ii) Electroless Palladium and Immersion Gold (EPIG), (iii) Immersion Gold, Electroless Palladium and Immersion Gold (IGEPIG), as well as other types of barrier layer processes.

The key attributes are that there is a barrier material (e.g., nickel (Ni) or palladium (Pd) in the above examples) that cover the entire exposed via surface, where the barrier material is of sufficient thickness to prevent Cu migration into the Au at elevated temperatures (e.g. 350-400 C for 1-2 hours). This also includes a continuous layer of this metal finish over the entire TGV outer surface. An anneal step to remove embedded hydrogen from the coating may also be used.

Once the conductive barrier layer is deposited, additional layers (e.g., Au) are deposited onto the lid wafer and the lid wafer is then bonded to the MEMS substrate in a specific oxygen environment. The barrier layer provides reliable performance over a range of process and operational environmental parameters (% O₂, humidity, temperature, etc.).

FIG. 5A illustrates a cross-sectional view of an example pinched via, viewed near the glass substrate surface at the top of the via. As shown, the conductive Pd barrier layer is disposed on the outside of the Cu via, and covers the glass-to-copper interface at the via perimeter. It is important to have full coverage of the Pd barrier layer across the entire TGV surface, and to have a uniform thickness. Accomplishing complete coverage is difficult for the pinch via design. The thickness of the barrier layer tends to be greater at the top/outside than it is within the cavity of the pinched via. See, for example, FIG. 6, which shows the percent coverage of the Pd barrier layer at various depths of a pinched via into the glass substrate. FIG. 6 illustrates that coverage near the top of the pinched via is complete or nearly complete, while coverage deep into the via cavity may be substantially reduced. Techniques such as sonification may be used to drive the Pd into the via cavity, thereby resulting in a thicker and more uniform barrier layer deep into the cavity of the via. Application of the barrier layer as described herein on a planar via, on the other hand, tends to result in a barrier layer of uniform thickness, which in turn results in complete or near complete coverage across the entire planar via.

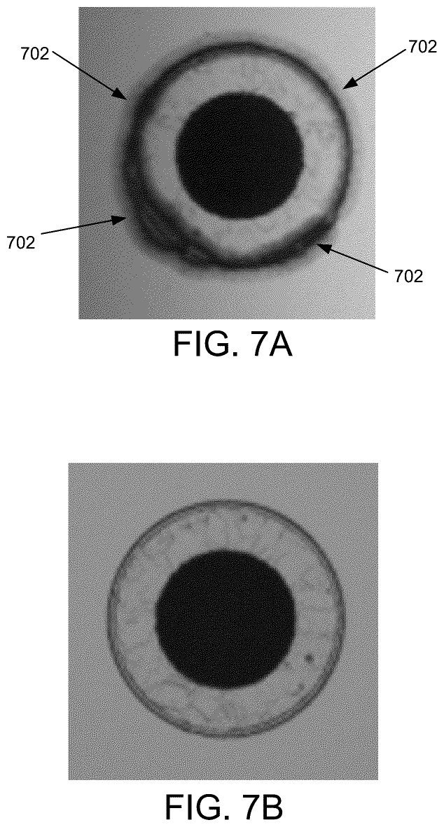

FIG. 7A illustrates an example top-view of a via with no Pd barrier (or poor Pd barrier placement), and FIG. 7B illustrates an example top-view of a via with substantial Pd barrier layer coverage. In both FIGS. 7A and 7B, the dark circle in the center of the via represents the cavity of the via (sec, e.g., FIG. 3A). FIG. 7A shows a substantial amount of cupric oxide (CuO) corrosion 702 formed about the surface of the via due to copper that has migrated through the gold layer, while FIG. 7B is relatively free of CuO corrosion at the surface of the via due to the presence of the Pd barrier layer.

Placement of conductive barrier layers as described herein may be accomplished using various techniques such as electroless plating (e.g., ENIG, EPIG or IGEPIG), sputtering, atomic layer deposition (ALD), chemical vapor deposition (CVD), physical vapor deposition (PVD), among others. Chemically-based techniques such as electroless plating tend to produce better results for cavity-based vias (e.g., pinched vias), because chemically-based techniques facilitate propagation of the barrier material into the cavity of the via. And, as mentioned herein, sonication techniques may be used to further enhance the distribution of the barrier material into the cavity of the via.

While example embodiments have been particularly shown and described, it will be understood by those skilled in the art that various changes in form and details may be made therein without departing from the scope of the embodiments encompassed by the appended claims.

What is claimed is:

1. A method of preventing corrosion associated with an electrically-conductive through-glass via (TGV), comprising:
forming a TGV in a glass substrate for use in a microelectromechanical system (MEMS) device, the TGV having a first end and a second end, and at least partially comprising copper;
applying a conductive barrier layer on the first end of the TGV and/or the second end of the TGV.

2. The method of claim 1, further comprising applying a metal layer over the conductive barrier layer.

3. The method of claim 1, further comprising extending the conductive barrier layer over the first end of the TGV, and over at least a portion of the glass substrate encompassing the end of the TGV, such that the conductive barrier layer overlaps a boundary between the TGV and the glass substrate.

4. The method of claim 1, further comprising applying the conductive barrier layer using an electroless plating process.

5. The method of claim 4, wherein the electroless plating technique is electroless palladium and immersion gold (EPIG).

6. The method of claim 4, wherein the electroless plating technique is immersion gold, electroless palladium, and immersion gold (IGEPIG).

7. The method of claim 4, wherein the electroless plating technique is Electroless Nickel and Immersion Gold (ENIG).

8. The method of claim 1, wherein forming the TGV in the glass substrate further comprises forming a planar TGV in the glass substrate.

9. The method of claim 1, wherein forming the TGV in the glass substrate further comprises forming a pinched TGV in the glass substrate.

10. An electrically-conductive through-glass via (TGV) structure, comprising:
a TGV formed in a glass substrate for use in a microelectromechanical system (MEMS) device, the TGV having a first end and a second end, and at least partially comprising copper; and
a conductive barrier layer applied on the first end of the TGV and/or the second end of the TGV.

11. The structure of claim 10, further comprising a metal layer disposed over the conductive barrier layer.

12. The structure of claim 10, wherein the conductive barrier layer extends over the first end of the TGV, and over at least a portion of the glass substrate encompassing the end of the TGV, such that the conductive barrier layer overlaps a boundary between the TGV and the glass substrate.

13. The structure of claim 10, wherein the conductive barrier layer is applied using an electroless plating process.

14. The structure of claim 13, wherein the electroless plating technique is electroless palladium and immersion gold (EPIG).

15. The structure of claim 13, wherein the electroless plating technique is immersion gold, electroless palladium, and immersion gold (IGEPIG).

16. The structure of claim 13, wherein the electroless plating technique is Electroless Nickel and Immersion Gold (ENIG).

17. The structure of claim 10, wherein the TGV is a planar TGV.

18. The structure of claim 10, wherein the TGV is a pinched TGV.

19. A microelectromechanical system (MEMS) component, comprising:
a glass substrate that hosts a MEMS device;
a glass lid disposed on the glass substrate and encompassing the MEMS device within a cavity;
a through-glass via (TGV) formed in the glass lid, the TGV having a first end at an exterior of the glass lid, a second end electrically coupled to the MEMS device, and at least partially comprising copper; and
a conductive barrier layer applied on the first end of the TGV and/or the second end of the TGV.

20. The MEMS component of claim 19, wherein the conductive barrier layer extends over the first end of the TGV, and over at least a portion of the exterior of the glass lid, such that the conductive barrier layer overlaps a boundary between the TGV and the glass lid.
